(19) United States
(12) Patent Application Publication
(10) Pub. No.: US 2020/0295214 A1
(43) Pub. Date: Sep. 17, 2020

(54) PN JUNCTIONS WITH MECHANICALLY EXFOLIATED GALLIUM OXIDE AND GALLIUM NITRIDE

(71) Applicants: Jossue Montes, Mesa, AZ (US); Chen Yang, Tempe, AZ (US); Houqiang Fu, Tempe, AZ (US); Jingan Zhou, Tempe, AZ (US); Yuji Zhao, Chandler, AZ (US)

(72) Inventors: Jossue Montes, Mesa, AZ (US); Chen Yang, Tempe, AZ (US); Houqiang Fu, Tempe, AZ (US); Jingan Zhou, Tempe, AZ (US); Yuji Zhao, Chandler, AZ (US)

(21) Appl. No.: 16/818,659

(22) Filed: Mar. 13, 2020

Related U.S. Application Data
(60) Provisional application No. 62/819,021, filed on Mar. 15, 2019.

(51) Int. Cl. H01L 31/072; H01L 31/0224; H01L 31/0304; H01L 31/032; H01L 31/0336; H01L 31/18

(52) U.S. Cl. CPC H01L 31/072; H01L 31/022425; H01L 31/18; H01L 31/032; H01L 31/0336; H01L 31/03044

(57) ABSTRACT

A pn heterojunction diode includes a p-GaN substrate, a layer of β-Ga₂O₃ on a surface of the p-GaN substrate, an n contact disposed on a surface of the β-Ga₂O₃ layer opposite the p-GaN substrate, and a p contact disposed on the surface of the p-GaN substrate and proximate the GaN substrate. Fabricating a pn heterojunction diode includes depositing a metal on a first surface of a β-Ga₂O₃ wafer to form a first contact on the first surface of the β-Ga₂O₃ wafer, adhering the first contact to an adhesive material, thereby exposing a second surface of the β-Ga₂O₃ wafer, wherein the second surface is opposite the first surface, exfoliating layers of the β-Ga₂O₃ wafer from the second surface to yield an exfoliated surface on the β-Ga₂O₃ wafer, and contacting the exfoliated surface with a surface of a p-GaN substrate to yield a stack.

### CROSS-REFERENCE TO RELATED APPLICATION

This application claims the benefit of U.S. Patent Application No. 62/819,021 entitled “PN JUNCTIONS WITH MECHANICALLY EXFOLIATED GALLIUM OXIDE AND GALLIUM NITRIDE” and filed on Mar. 15, 2019, which is incorporated herein by reference in its entirety.

### STATEMENT OF GOVERNMENT INTEREST

This invention was made with government support under 1542160 awarded by the National Science Foundation and under 80NSSC17K0768 awarded by the National Aeronautics and Space Administration. The government has certain rights in the invention.

### TECHNICAL FIELD

This invention relates to pn junctions with mechanically exfoliated gallium oxide and gallium nitride.

### BACKGROUND

Recent developments of InGaN solar cells have benefited from research efforts in other III-nitride optoelectronic devices, such as light-emitting diodes and laser diodes. However, the performance of current InGaN solar cells is still unsatisfactory, especially when compared with well-developed photovoltaic devices based on silicon or III-IV materials. For instance, a typical conversion efficiency of some GaAs solar cells is more than 20%. In comparison, however, it is still less than 5% for some InGaN solar cells.

### SUMMARY

pn junctions are constructed from mechanically exfoliated ultrawide bandgap (UWBG) beta-phase gallium oxide (β-Ga₂O₃) and p-type gallium nitride (p-GaN). Atomic force microscopy (AFM) scans of the exfoliated β-Ga₂O₃ flakes show smooth surfaces with an average roughness of 0.647 nm, and transmission electron microscopy (TEM) scans reveal flat, clean interfaces between the β-Ga₂O₃ flakes and p-GaN. The device shows a rectification ratio around 541.3 (V₊₅/V₋₅). Diode performance improves over the temperature range of 25° C. and 200° C., leading to an unintentional donor activation energy of 135 meV. As the thickness of the β-Ga₂O₃ flake increases from 100 nm to 20 μm, the electrical performance of the pn junction does not change appreciably.

In a first general aspect, fabricating a pn heterojunction diode includes depositing a metal on a first surface of a β-Ga₂O₃ wafer to form a first contact on the first surface of the β-Ga₂O₃ wafer, adhering the first contact to an adhesive material, thereby exposing a second surface of the β-Ga₂O₃ wafer, exfoliating layers of the β-Ga₂O₃ wafer from the second surface to yield an exfoliated surface on the β-Ga₂O₃ wafer, and contacting the exfoliated surface with a surface of a p-GaN substrate to yield a stack. The second surface is opposite the first surface. The stack includes the p-GaN substrate and the exfoliated β-Ga₂O₃ wafer. The exfoliated surface on the β-Ga₂O₃ wafer is in contact with the p-GaN substrate. The p-GaN substrate includes a second contact on the surface of the p-GaN substrate, and the first contact is proximate the second contact.

Implementations of the first general aspect may include one or more of the following features.

In some cases, the first contact is an n contact. Depositing the metal on the first surface of the β-Ga₂O₃ wafer includes depositing one or more of a titanium layer, an aluminum layer, a nickel layer, and a gold layer on the first surface of the β-Ga₂O₃ wafer or an intermediate surface thereon. Depositing the metal can include electron beam evaporation. The first contact is typically annealed before adhering the first contact to an adhesive material. Exfoliating layers of the β-Ga₂O₃ wafer can include removing layers of the β-Ga₂O₃ wafer with an adhesive tape. The second contact is typically a p contact. The first general aspect can further include depositing the second contact on the p-GaN substrate, where depositing the second contact includes depositing one or more of a palladium layer, a nickel layer, and a gold layer on the p-GaN substrate or an intermediate layer thereon. In some cases, depositing the second contact includes electron beam evaporation. The first general aspect can further include annealing the second contact.

In a second general aspect, a pn heterojunction diode includes a p-GaN substrate, a layer of β-Ga₂O₃ on a surface of the p-GaN substrate, an n contact disposed on a surface of the β-Ga₂O₃ layer opposite the p-GaN substrate, and a p contact disposed on the surface of the p-GaN substrate and proximate the GaN substrate, defining a gap between the p contact and the n contact.

Implementations of the first general aspect may include one or more of the following features.

The n contact typically includes a layer of titanium, a layer of aluminum, a layer of nickel, or a layer of gold. In some cases, a thickness of the n contact is in a range between 100 nm and 300 nm. The p contact includes a layer of palladium, a layer of nickel, or a layer of gold. A thickness of the p contact is in a range between 100 nm and 300 nm. A thickness of the lay−er of β-Ga₂O₃ is between about 50 nm and about 25 μm. A thickness of the layer of β-Ga₂O₃ is between about 100 nm and about 20 μm. The ideal threshold voltage of the pn heterojunction diode is between about 3 V and about 3.5 V.

The details of one or more embodiments of the subject matter of this disclosure are set forth in the accompanying drawings and the description. Other features, aspects, and advantages of the subject matter will become apparent from the description, the drawings, and the claims.

### BRIEF DESCRIPTION OF THE DRAWINGS

FIGS. 1A-1G depict formation of a pn junction including beta-phase gallium oxide (β-Ga₂O₃) and p-type gallium nitride (p-GaN). FIG. 1A depicts cleavage of a bulk (2̅01) β-Ga₂O₃ wafer to expose the (100) plane. FIG. 1B depicts an n contact as deposited on the β-Ga₂O₃. FIG. 1C depicts thermal tape adhered to the n contact. FIG. 1D depicts exfoliation of the exposed β-Ga₂O₃ with adhesive tape. FIG. 1E depicts positioning of the β-Ga₂O₃, metal, and thermal tape stack on p-type GaN proximate a previously deposited p-contact. FIG. 1F depicts placement of the stack from FIG. 1E on a vacuum-sealed hot plate to facilitate removal of the thermal tape.

FIG. 1G depicts the resulting pn junction after removal of the thermal tape.

FIG. 2A shows a height profile of a mechanically exfoliated flake (without metal).

FIG. 2B is an XRD rocking curve of the bulk (2̅01) β-Ga₂O₃ sample.

FIG. 3 shows a semi-log plot of the conductance with respect to temperature.

### DETAILED DESCRIPTION

Beta-phase gallium oxide (β-Ga₂O₃) is a stable ultrawide bandgap (UWBG) semiconductor with a 4.6-4.9 eV bandgap, which enables it to be used in deep ultra violet (DUV) and ultra-high power applications. With a high theoretical breakdown electric field of 8 MV/cm, saturation electron velocity of 2×10⁷ cm/s, and Baliga's Figure of Merit (BFOM) of 3214.1, β-Ga₂O₃ shows potential to perform beyond current high-power semiconductors such as GaN and SiC. Large, low-cost, high-quality wafers of bulk β-Ga₂O₃ have a unique monoclinic crystal structure and are also readily available. β-Ga₂O₃ is a 3D crystal that belongs to the C2/m space group with lattice constants a=1.22 nm, b=0.303 nm, and c=0.580 nm, with angle β=103.83°. Because its a lattice vector, which points in the [100] direction, is larger than the other two, a mechanical ‘peeling off’ or ‘cleaving’ of layers of the β-Ga₂O₃ is possible. The layers may then be transferred to any arbitrary substrate, where they will remain well-adhered, surviving subsequent ultrasonic wet cleaning and photolithographic processes. The peeling off of layers is known as“mechanical exfoliation.”

Fabrication of pn heterojunction diodes between mechanically exfoliated β-Ga₂O₃ and p-type GaN and the resulting diodes are described. The resulting diodes show a high rectification ratio and the turn-on voltage is comparable a simulation conducted using software available from Silvaco, Inc. Electrical properties, including the turn-on voltage and ideality factor improved in a series of elevated temperatures from 25° C. to 200° C. By controlling the peeling off process, diodes with different thicknesses of β-Ga₂O₃ were fabricated, and the device characteristics with respect to β-Ga₂O₃ thickness were also analyzed.

The as-received β-Ga₂O₃ wafer is of the (−201) orientation. It is doped with impurities such as Sn. A diamond-tipped pen, suitable for cleaving/slicing through materials, is used to cleave the wafer. For a (−201)-oriented β-Ga₂O₃ wafer, this cleaving is done parallel to the wafer flat. Cleaving the wafer in this direction will expose the (100) plane (or “face”) of the β-Ga₂O₃ wafer. Relatively thick flakes of (100)-oriented β-Ga₂O₃ can be removed from the freshly-cleaved bulk β-Ga₂O₃ wafer using ordinary sample tweezers. The thicknesses of these flakes can range from tens of nanometers up to hundreds of microns. A relatively thick flake, for example, about 50 μm thick, was removed. Using electron beam evaporation, metal contacts were deposited on this flake of (100)-oriented β-Ga₂O₃. The metal stack consisted of Ti (20 nm)/Al (30 nm)/Ni (20 nm)/Au (100 nm). This metal contact is then annealed in N₂ at 470° C. for 1 minute. This is the n contact, which is now deposited on the (100) β-Ga₂O₃, which is the n side of the pn heterojunction.

The (100) β-Ga₂O₃/metal stack is then placed upside down on some thermal tape, with the metal side down. Hereinafter, “β-Ga₂O₃” refers to (100)-oriented β-Ga₂O₃. With the β-Ga₂O₃/metal stack secured on the thermal tape, ordinary scotch tape is placed on the stack, then peeled off. This removes layers of β-Ga₂O₃, thereby reducing its thickness (from a starting thickness was 50 μm) but not affecting the metal contacts. This removing of layers with scotch tape is another form of mechanical exfoliation, as it includes the removing of layers from the material. This process of removing layers with scotch tape is repeated as many times as necessary until the thickness of the β-Ga₂O₃ is at a desired level.

The thermal tape/metal/β-Ga₂O₃ stack is then placed on a different semiconductor material, p-type gallium nitride (p-GaN). The p-GaN wafer will have already had a p contact deposited on it beforehand in the same manner (e.g., electron beam evaporation) though with different metals to form the p contact (e.g., Pd (30 nm)/Ni (20 nm)/Au (150 nm)). The p contact stack should have been annealed (e.g., 1000° C. in N₂ for 30 seconds). Additionally, the p-GaN/metal should have been cleaned beforehand in an ultrasonic wash using acetone for 5 minutes followed by IPA for 5 minutes, followed by drying.) The thermal tape/metal/β-Ga₂O₃ stack is placed down on the p-GaN, proximal to the p contact (i.e., not on top of the p contact), and the thermal tape is pressed down firmly so it adheres to the p-GaN surface. The entire sample is then placed, upside down, on a pre-heated hot plate, so that the non-sticky side of the thermal tape is in contact with the surface of the hot plate. Ideally the hot plate works with vacuum suction such that the sample is sucked down firmly and flatly against the surface of the hot plate. This helps with making sure the thermal tape is evenly contacting the hot place, since uneven contact will result in uneven thermal tape breakdown. The sample should be heated on the hot place for 2 minutes, after which, the adhesive strength of the thermal tape should vanish (this is based on the manufacturer, REVALPHA, guidelines). The entire sample may be easily removed from the tape and be ready for electrical testing.

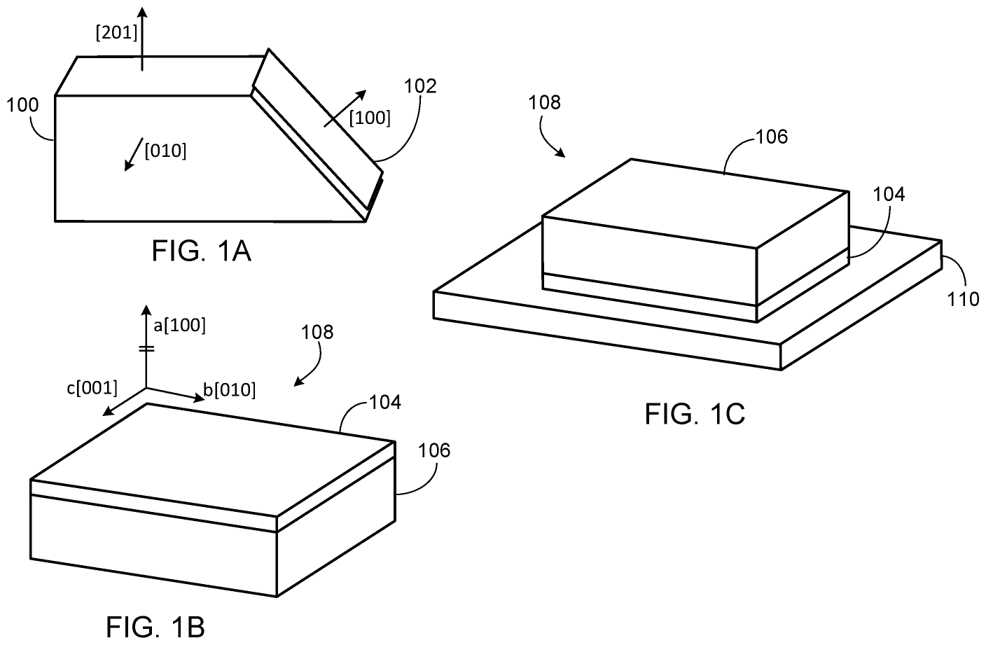

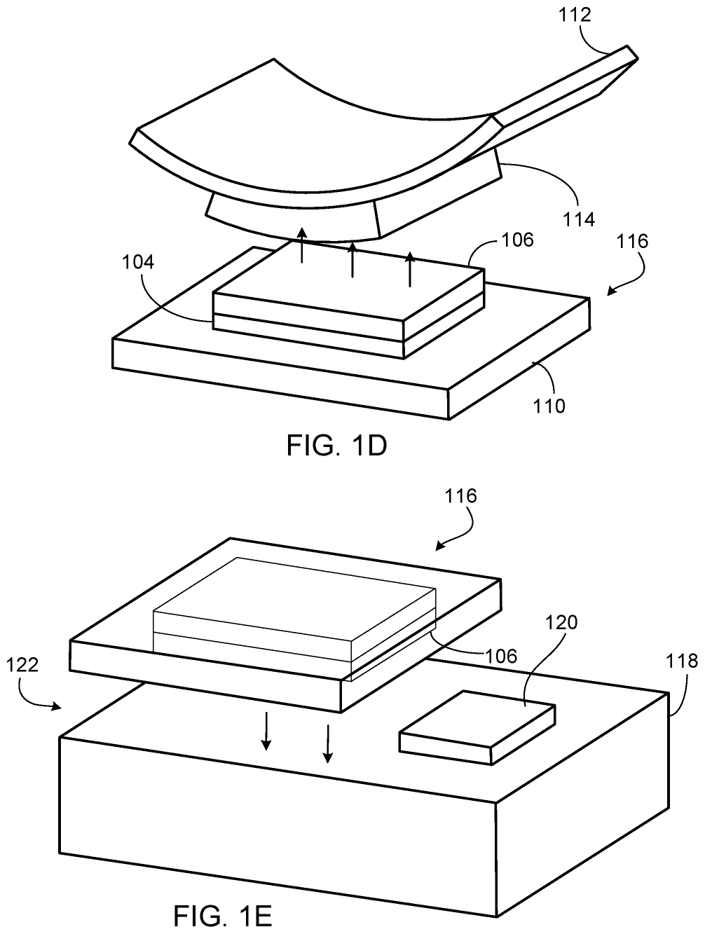

A p-type GaN target substrate consisting of 300 μm bulk GaN with 300 nm of p-GaN (N_{A}=10¹⁹ cm⁻³) was obtained. The p-GaN was cleaned in acetone and isopropyl alcohol (IPA) for 5 minutes each under ultrasonic agitation in order to remove any residual organic contamination on the surface. Metal stacks of Pd (30 nm)/Ni (20 nm)/Au (150 nm) were deposited using electron beam evaporation on the p-GaN and subsequently annealed under N₂ at 1000° C. for 30 s to form the p contact. 2-inch wafers of (2̅01)-oriented β-Ga₂O₃ (Sn doping, N_{D}=5×10¹⁸ cm⁻³) were purchased from Tamura Corporation with bulk thickness 0.65±0.02 mm. These bulk wafers were diced using a diamond tip so as to expose the (100) plane, and a thick fragment of β-Ga₂O₃ (˜500 μm) was removed. FIG. 1A depicts cleavage of the bulk (2̅01) wafers 100 of β-Ga₂O₃ to expose the (100) plane 102.

Using electron beam evaporation, metal stacks of Ti (20 nm)/Al (30 nm)/Ni (20 nm)/Au (100 nm) were deposited on the cleaved β-Ga₂O₃ fragment to form the n contact. FIG. 1B depicts a metal layer 104 disposed on the β-Ga₂O₃ fragment 106 to form the n contact 108. The contact 108 was subsequently annealed in N₂ at 470° C. for 1 minute. As depicted in FIG. 1C, the metal-semiconductor stack (n contact) 108 was placed upside down on thermal tape 110 (e.g., Revalpha Heat Release tape (#3193MS)) with the β-Ga₂O₃ 106 exposed. As depicted in FIG. 1D, adhesive tape (e.g., SCOTCH tape) 112 was used to peel off layers 114 of β-Ga₂O₃ from the bulk 106, reducing the thickness over repeated exfoliations. After the final exfoliation with the adhesive tape 112, the β-Ga₂O₃ 106, metal 104, and thermal tape 110 stack 116 was then transferred to a p-GaN substrate 118, as depicted in FIG. 1E. The backside of the thermal tape 110 was pressed down firmly on the p-GaN substrate 118 proximate a p-contact 120 (e.g., Pd/Ni/Au). The β-Ga₂O₃ 106 adhered to the p-GaN substrate 118 by its own pseudo-Van der Waals attractive forces—no adhesive material was required. As depicted in FIG. 1F, the entire β-Ga₂O₃/p-GaN structure 122 was placed upside down on a hot plate 124 (i.e., with the thermal tape 110 in contact with the hot plate) set to 120° C. with vacuum seal beneath. The upside down placement and vacuum seal ensured that the heat was evenly distributed across the thermal tape 110 so that the adhesion strength of the tape evenly decreased across the area of the tape. After 2 minutes on the hot plate 124, the adhesive strength of the thermal tape 110 vanished completely, and the stack was separated cleanly from the tape to yield the pn junction 126 depicted in FIG. 1G. Mechanical exfoliation by this method resulted in β-Ga₂O₃ flakes ranging between tens of nanometers to several hundred microns, depending on the number of times peeling off is performed.

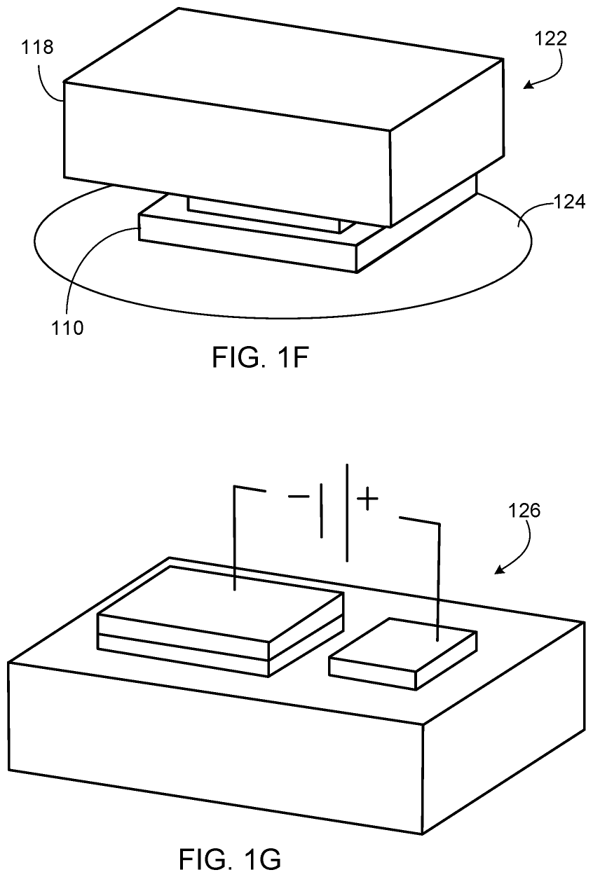

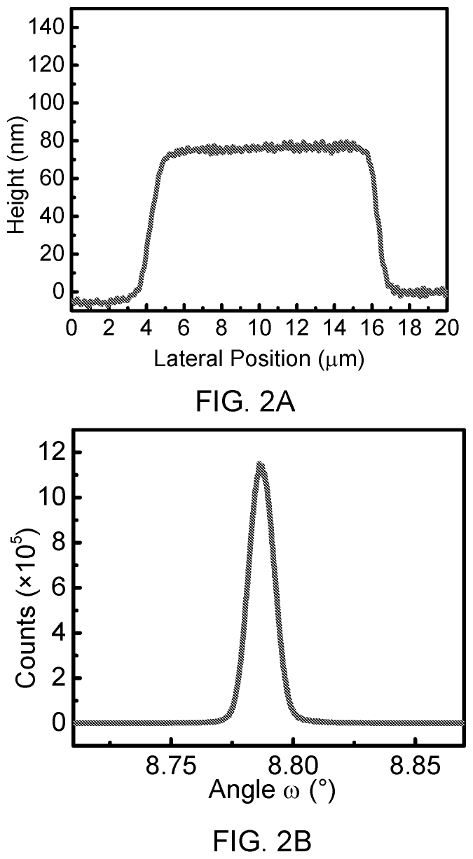

Atomic force microscopy (AFM) scans were performed using a Bruker Multimode instrument to examine the surface roughness of the exfoliated flakes. Using a 5×5 μm square area for each scan size, several scans showed an average surface roughness of 0.647 nm. High resolution x-ray diffraction (HR-XRD) scans were performed on the bulk (as-received) β-Ga₂O₃ to examine the crystal quality. The scans were carried out with a PANalytical X'Pert Pro diffractometer using Cu Kα1 radiation, a hybrid monochromator for the incident beam optics and a triple axis module for diffracted beam optics. The full-width at half-maximum of the (2̅01) and (010) planes is 87 arcsec and 90 arcsec, respectively. FIG. 2A shows the height profile of a 20 m exfoliated flake. Transmission electron microscopy was used to investigate the interfaces of the device. A cross-sectional scan, prepared using focused ion beam (FIB), is shown in FIG. 2B, with the layer thickness indicated by dashed lines. The β-Ga₂O₃ layer is flat, consistent with its characterization as a pseudo-2D material.

A typical I-V characteristic of the heterojunction diode by a Keithley 2410 source meter was obtained. When a forward bias was applied to the heterojunction, the current increased to a large value (approximate 1.2 mA at 10 V). The turn-on voltage is defined as the voltage value at which significant current (1×10⁻⁵A) begins to flow. However, at reverse bias, the device showed a rectification property with a rectification ratio around 541.3 (V₊₅/V₋₅). To rule out the possibility of having a Schottky diode, which could be formed by the electrode metal on the β-Ga₂O₃ flake accidently contacting with the p-GaN, the I-V characteristic of one probe directly placed on p-GaN, which formed a Schottky barrier, was tested. The comparison curve shows a drastic difference between the heterojunction and the Schottky barrier, with huge disparity in turn-on voltage and reverse leakage. To further verify the performance of the diode, commercial software from Silvaco, Inc., was used to simulate the energy band alignment for the pn junction. In the simulation, the p-GaN doping concentration was N_{A}=10¹⁹ cm⁻³ and the β-Ga₂O₃ doping concentration was N_{D}=5×10¹⁸ cm⁻³. The β-Ga₂O₃ bandgap was set to 4.85 eV and the p-GaN bandgap was 3.4 eV. The electron affinity of β-Ga₂O₃ was set to 4.0 eV. Using these parameters, the extracted band structure showed a valence and conduction band offsets of 1.27 and 0.11 eV, respectively. Several of the diodes were fabricated and tested, and their turn-on voltages were comparable to the calculated ideal turn-on voltage of 3.2 V (as determined by Silvaco simulations), thus confirming that the exfoliated β-Ga₂O₃ formed a heterojunction diode with p-GaN.

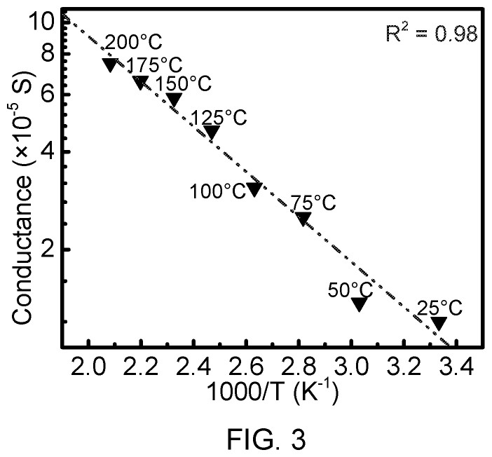

Temperature-dependent electrical tests were conducted in the range of 25° C. to 200° C. High-temperature I-V characteristics and a decrease of the ideality factor and turn-on voltage of the diode with increasing temperature were observed This increased electrical behavior is due at least in part to the improvement in diffusion current across the heterojunction. The conductance was given by differential conductance at 3.5 V forward bias and can be seen in FIG. 3. The activation energy estimated from an Arrhenius plot is 135 meV over the temperature range considered, implying that improvement of n-type conductivity in β-Ga₂O₃ is due in small part to the activation of unintentional deep donors, namely oxygen vacancies and other impurities. However, due to the very high doping concentrations used in this heterojunction, the contribution of the oxygen vacancies to the conduction is believed to be minimal.

The electrical characteristics of the diodes as a function of different β-Ga₂O₃ thicknesses were also studied. For the 100 nm, 5 μm, and 20 μm diodes, the I-V characteristics were found to be similar across the thicknesses considered.

Thus, a pn heterojunction diode constructed between mechanically exfoliated β-Ga₂O₃ and p-GaN was fabricated. The electrical character of the pn junctions was tested with I-V and temperature measurements, and exfoliated β-Ga₂O₃ flakes measuring 100 nm, 5 μm, and 20 μm were compared. It was observed that the electrical properties of the diodes become better as temperature increased up to 200° C. As the thicknesses of the β-Ga₂O₃ flakes increased, the device performance remained consistent. The unintentional donor activation energy was calculated as 135 meV in the temperature range studied. Across all thicknesses, the pn junction turn-on voltage tended toward the ideal turn-on voltage of 3.2 V, as determined by simulation.

Although this disclosure contains many specific embodiment details, these should not be construed as limitations on the scope of the subject matter or on the scope of what may be claimed, but rather as descriptions of features that may be specific to particular embodiments. Certain features that are described in this disclosure in the context of separate embodiments can also be implemented, in combination, in a single embodiment. Conversely, various features that are described in the context of a single embodiment can also be implemented in multiple embodiments, separately, or in any suitable sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

Particular embodiments of the subject matter have been described. Other embodiments, alterations, and permutations of the described embodiments are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results.

Accordingly, the previously described example embodiments do not define or constrain this disclosure. Other changes, substitutions, and alterations are also possible without departing from the spirit and scope of this disclosure.

What is claimed is:

1. A method of fabricating a pn heterojunction diode, the method comprising:
depositing a metal on a first surface of a β-Ga₂O₃ wafer to form a first contact on the first surface of the β-Ga₂O₃ wafer;
adhering the first contact to an adhesive material, thereby exposing a second surface of the β-Ga₂O₃ wafer, wherein the second surface is opposite the first surface;
exfoliating layers of the β-Ga₂O₃ wafer from the second surface to yield an exfoliated surface on the β-Ga₂O₃ wafer; and
contacting the exfoliated surface with a surface of a p-GaN substrate to yield a stack, wherein the stack comprises the p-GaN substrate and the exfoliated β-Ga₂O₃ wafer, the exfoliated surface on the β-Ga₂O₃ wafer is in contact with the p-GaN substrate, the p-GaN substrate comprises a second contact on the surface of the p-GaN substrate, and the first contact is proximate the second contact.

2. The method of claim 1, wherein the first contact is an n contact.

3. The method of claim 1, wherein depositing the metal on the first surface of the β-Ga₂O₃ wafer comprises depositing one or more of a titanium layer, an aluminum layer, a nickel layer, and a gold layer on the first surface of the β-Ga₂O₃ wafer or an intermediate surface thereon.

4. The method of claim 3, wherein depositing the metal comprises electron beam evaporation.

5. The method of claim 1, further comprising annealing the first contact before adhering the first contact to an adhesive material.

6. The method of claim 1, wherein exfoliating layers of the β-Ga₂O₃ wafer comprises removing layers of the β-Ga₂O₃ wafer with an adhesive tape.

7. The method of claim 1, wherein the second contact is a p contact.

8. The method of claim 1, further comprising depositing the second contact on the p-GaN substrate, wherein depositing the second contact comprises depositing one or more of a palladium layer, a nickel layer, and a gold layer on the p-GaN substrate or an intermediate layer thereon.

9. The method of claim 8, wherein depositing the second contact comprises electron beam evaporation.

10. The method of claim 8, further comprising annealing the second contact.

11. A pn heterojunction diode comprising:
a p-GaN substrate;
a layer of β-Ga₂O₃ on a surface of the p-GaN substrate;
an n contact disposed on a surface of the β-Ga₂O₃ layer opposite the p-GaN substrate; and
a p contact disposed on the surface of the p-GaN substrate and proximate the GaN substrate, defining a gap between the p contact and the n contact.

12. The pn heterojunction diode of claim 11, wherein the n contact comprises a layer of titanium, a layer of aluminum, a layer of nickel, or a layer of gold.

13. The pn heterojunction diode of claim 12, wherein a thickness of the n contact is in a range between 100 nm and 300 nm.

14. The pn heterojunction diode of claim 11, wherein the p contact comprises a layer of palladium, a layer of nickel, or a layer of gold.

15. The pn heterojunction diode of claim 14, wherein a thickness of the p contact is in a range between 100 nm and 300 nm.

16. The pn heterojunction diode of claim 11, wherein a thickness of the layer of β-Ga₂O₃ is between about 50 nm and about 25 μm.

17. The pn heterojunction diode of claim 16, wherein a thickness of the layer of β-Ga₂O₃ is between about 100 nm and about 20 μm.

18. The pn heterojunction diode of claim 11, wherein the ideal threshold voltage of the pn heterojunction diode is between about 3 V and about 3.5 V.
